(19) United States
(12) Patent Application Publication
(10) Pub. No.: US 2009/0032285 A1
(43) Pub. Date: Feb. 5, 2009

(54) MULTI-LAYER CIRCUIT SUBSTRATE MANUFACTURING METHOD AND MULTI-LAYER CIRCUIT SUBSTRATE

(75) Inventors: Yoji Ueda, Osaka (JP); Susumu Matsuoka, Osaka (JP); Rikiya Okimoto, Osaka (JP); Shozo Ochi, Osaka (JP); Satoru Tomekawa, Osaka (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 11/814,698

(22) PCT Filed: Jan. 27, 2005
(86) PCT No.: PCT/JP2005/001136

§ 371 Date: Jul. 25, 2007

(51) Int. Cl. H05K 3/46; H05K 1/14; H05K 1/00

(52) U.S. Cl. 174/250; 156/308.2; 156/307.7; 428/200; 156/182

(57) ABSTRACT

A method of manufacturing a multilayered circuit board includes the steps of: manufacturing a laminated body by laminating a prepreg of a predetermined thickness on at least one surface of a double-sided circuit board having a grounding link and a signal wiring patterned on both surfaces thereof; and applying heat and pressure to the laminated body and completing a layered structure in which the signal wiring is laid inside the prepreg at a boundary between the double-sided circuit board and the prepreg, wherein prepreg sheets of a predetermined thickness are used in a completed layered structure so that a thickness of a prepreg of the double-sided circuit board is smaller than a distance between a surface of the prepreg on a side not opposed to the double-sided circuit board and the signal wiring laid inside the prepreg.

This application is a U.S. national phase application of PCT International Patent Application No. PCT/JP2005/001136 filed Jan. 27, 2005.

### TECHNICAL FIELD

The present invention relates to a method of manufacturing a multilayered circuit board, and a multilayered circuit board.

### BACKGROUND ART

In recent years, there are demands for miniaturization, weight saving, high-speed signal processing and also high-density mounting as to a multilayered circuit board in conjunction with miniaturization, weight saving and increase in performance of electronics devices. Concerning such demands, it is necessary to rapidly advance circuit board technologies as to going vertical and multilayered, reducing diameters and pitches of via holes, rendering circuit patterns finer and the like. However, it has already become very difficult to meet such demands in the case of a conventional multilayered circuit board wherein an electrical connection in an insulating layer is made by a through-hole structure.

For that reason, multilayered circuit boards including new structures and methods of manufacturing the same were developed. As a representative example thereof, a circuit formation board having a complete IVH (Inner Via Hole) structure was developed, which had the electrical connection in the insulating layer secured by a conductive paste (refer to Japanese Patent No. 2601128 for instance) instead of the through-hole structure which had conventionally been the mainstream of inner-insulating layer connections of the multilayered circuit board. Details thereof will be omitted.

Furthermore, a method of manufacturing a multilayered circuit board for realizing high productivity was developed (refer to Japanese Patent No. 3231537 (such as claim 2, FIG. 7) for instance). FIGS. 8(a) to (c) show a manufacturing procedure of the conventional multilayered circuit board by taking a 6-layered circuit board as an example.

FIG. 8(a) shows a lamination sectional view of the 6-layered circuit board. In FIG. 8(a), reference characters 1a, 1b and 1c denote aramid-epoxy sheets composed of a composite material having an aramid nonwoven fabric impregnated with a thermosetting epoxy resin (hereinafter, referred to as prepregs), where a through-hole formed by a laser or the like is filled with a conductive paste 2 composed of Cu powder and the thermosetting epoxy resin.

Reference characters 5a and 5b denote double-sided circuit boards, and circuit patterns 3 formed on both sides thereof are electrically connected by the conductive paste 2 filled in the through-holes provided in predetermined positions. Reference characters 4a and 4b denote metallic foils such as Cu.

First, as shown in FIG. 8(a), the metallic foil 4b, prepreg 1c, double-sided circuit board 5b, prepreg 1b, double-sided circuit board 5a, prepreg 1a and metallic foil 4a are sequentially laminated on a work stage (not shown). As for positioning of each of them, a positioning pattern (not shown) is used to position and stack them by image recognition or the like.

Next, heat and pressure are applied from above the metallic foil 4a on a top surface with a heated heater chip or the like (not shown) to melt resin components of the prepregs 1a, 1b and 1c, which adhere to the double-sided circuit boards 5a and 5b and the metallic foils 4a and 4b due to hardening of the resin components thereafter.

Next, heat and pressure are applied to both top and under surfaces by means of heat press so that the prepregs 1a, 1b and 1c cause the entire surfaces of the metallic foils 4a and 4b to adhere to the double-sided circuit boards 5a and 5b. At the same time, inner via hole connections are made by the conductive paste 2 between a circuit pattern 3 of the double-sided circuit board 5a and a circuit pattern 3 of the double-sided circuit board 5b, between the circuit pattern 3 of the double-sided circuit board 5a and the metallic foil 4a, and between the circuit pattern 3 of the double-sided circuit board 5b and the metallic foil 4b. FIG. 8(b) shows a sectional view of the 6-layered circuit board after the heat press.

Thereafter, the metallic foils 4a and 4b of an outermost layer are selectively etched to form the circuit pattern 3, and thus the 6-layered circuit board is collectively obtained. FIG. 8(c) shows a sectional view of the 6-layered circuit board after the etching.

However, the multilayered circuit board manufactured by the above conventional method had the following problems.

Nowadays, EMI (Electromagnetic Interference) noise is becoming relevant in conjunction with higher frequencies of electronic components. such as semiconductor devices mounted on the multilayered circuit board.

As one countermeasure against the EMI noise, the EMI noise can be shielded by covering an inner wiring layer with a large-area earth conductor layer called a solid pattern in the case of the multilayered circuit board or a package substrate of a package for mounting or housing the electronic components such as the semiconductor devices.

In the case where large-area earth conductors are placed on and under a wiring group as the countermeasure against the EMI noise, it is necessary to design and manufacture the board in view of impedance matching (50Ω for instance).

In the case of taking the impedance matching, it is necessary to design and manufacture the multilayered circuit board in view of a conductor width, a conductor thickness, an inter-conductor layer thickness and a permittivity of an insulating material used between the conductor layers.

FIGS. 9(a) to (c) show sectional views of arbitrary three conductor layers in an internal-layer portion of the multilayered circuit board manufactured by a conventional manufacturing method. As shown in the drawings, reference numeral 90 denotes an insulating layer for forming double-sided circuit boards (equivalent to 5a and 5b of FIG. 8(a)), and 91 denotes a portion of the prepreg (equivalent to 1a, 1b and 1c of FIG. 8(a)) on lamination in FIG. 8(a). Reference characters S1 to S3 denote signal wirings which are equivalent to wiring patterns of the double-sided circuit boards shown in FIGS. 8(a) to (c).

Reference character S1 of FIG. 9(a) denotes a signal line of relatively thin line width such as 100 μm or less, S2 of FIG. 9(b) denotes a signal line of relatively thick line width such as 5 mm, and S3 of FIG. 9(c) denotes a cross-section of a solid layer of a wide range.

Reference character T1 denotes a thickness of the insulating layer 90 of the double-sided circuit board used on lamination, and the thickness does not change even after the heat press. Reference characters T2′ to T4′ denote thicknesses of the prepregs 90 used on lamination after the heat press. Reference characters T2 to T4 are distances of signal wirings S1 to S3, which are indicated as the distances between surfaces opposed to ground wirings G2 and surfaces not contacting the prepregs 90 which are the insulating layers of the prepregs. To be more specific, T2 to T4 indicate the thicknesses from which dents of the prepregs 90 are subtracted respectively, the dents occurring due to the thicknesses of the signal wirings S1 denting on the prepreg sides because of joining of the double-sided circuit boards.

T1 and T2 to T4 have the same thickness before the heat press.

As shown in FIGS. 9(a) and (b), denting of the signal wirings S1 and S2 on the prepreg sides is different in degrees due to a difference in designed line width of the signal lines. Therefore, there are variations in the thicknesses of the prepregs 90 and prepregs 91 after the heat press, such as T1>T3>T2. In FIG. 9(c), a large-area solid layer is included as the signal wiring S3, where it is T1≈T4 because the pressure exerted on the prepreg 91 side is still smaller and the dent is hardly generated.

As shown in FIGS. 8(a) to 8(c), the circuit patterns 3 placed on both principal surfaces of the double-sided circuit boards 5a and 5b are different in wiring width and also density respectively. Because of these differences, there are individual significant variations in thickness of the prepregs 1a to 1c as the insulating layers laminated on the double-sided circuit boards 5a and 5b. Similarly, there arise variations in individual thickness of the prepregs 1a to 1c according to thickness of a copper foil used for wiring. For that reason, there arises a mismatch in characteristic impedance. There was a possibility that, once the mismatch in characteristic impedance arises, noise, transmission loss of a high-frequency signal and the like occur so that operations of electronic components such as semiconductor elements mounted thereon may become unstable.

### DISCLOSURE OF THE INVENTION

Thus, in view of the above conventional problems, an object of the present invention is to provide a method of manufacturing a high-performance multilayered circuit board and the multilayered circuit board, which can be stably driven at high frequencies with no mismatch in impedance.

To solve the above problems, the 1st aspect of the present invention is a method of manufacturing a multilayered circuit board, comprising:

manufacturing a laminated body by laminating a prepreg sheet of a predetermined thickness on at least one side of a double-sided circuit board having electrode wires patterned on both sides thereof; and

heating and pressurizing the laminated body for completing a layered structure in which the electrode wires are buried in the prepreg sheet at a boundary between the double-sided circuit board and the prepreg sheet so as to manufacture the multilayered circuit board, including said at least one layered structure, as an internal layer,

wherein, the thickness of a board body of the double-sided circuit board is equal to or smaller than a distance between a surface of the prepreg sheet on a side not opposed to the double-sided circuit board and the electrode wires buried inside the prepreg sheet in said layered structure which is completed, if the predetermined thickness of the prepreg sheet is t2′, the thickness of the board body of the double-sided circuit board is t1, and the thickness of the electrode wires is t0, there is a relation of:

t2′=α (α is a predetermined value satisfying 1≦α)·t1+k (k is a predetermined value satisfying 0<k≦1)·t0. (Formula 1)

Further, the 2nd aspect of the present invention is the method of manufacturing a multilayered circuit board according to the 1st aspect of the present invention, wherein the predetermined value α is a value corresponding to the thickness to of the electrode wires.

Further, the 3rd aspect of the present invention is the method of manufacturing a multilayered circuit board according to the 2nd aspect of the present invention, wherein the predetermined value α is substantially 1.05.

Further, the 4th aspect of the present invention is the method of manufacturing a multilayered circuit board according to the 1st aspect of the present invention, wherein:

the laminated body is manufactured by alternately positioning and stacking multiple double-sided circuit boards and multiple prepreg sheets, which includes the prepreg sheet; and

said layered structure is manufactured by heating and pressurizing both top and bottom surfaces of the laminated body and hardening the multiple prepreg sheets.

Further, the 5th aspect of the present invention is the method of manufacturing a multilayered circuit board according to the 1st aspect of the present invention, wherein:

the laminated body is manufactured by alternately positioning and stacking multiple double-sided circuit boards, which includes the double-sided circuit board, and multiple. prepreg sheets, which includes the prepreg sheet; and

said layered structure is manufactured by partially heating and pressurizing an arbitrary area of the laminated body and melting and then hardening a resin included in the multiple prepreg sheets so as to bond a circuit board group.

Further, the 6th aspect of the present invention is the method of manufacturing a multilayered circuit board according to the 1st aspect of the present invention, wherein:

a plurality of the laminated bodies are manufactured by stacking either multiple double-sided circuit boards, which includes the double-sided circuit board, or multiple prepreg sheets, which include the prepreg sheet, one by one; and

said layered structure is manufactured by stacking the plurality of the laminated bodies, partially heating and pressurizing arbitrary areas thereof and melting and then hardening a resin included in the multiple prepreg sheets so as to mutually bond them.

Further, the 7th aspect of the present invention is the method of manufacturing a multilayered circuit board according to the 4th aspect of the present invention, wherein:

alternately positioning and stacking the multiple double-sided circuit boards and the multiple prepreg sheets for manufacturing the laminated body includes placing copper foils at the beginning and end and placing the multiple prepreg sheets adjacently to the copper foils.

Further, the 10th aspect of the present invention is a multilayered circuit board including, as an internal layer, at least one layered structure composed of a double-sided circuit board having electrode wires patterned on both sides thereof and a prepreg sheet laminated on at least one side of the double-sided circuit board, wherein:

the electrode wires are buried in the prepreg sheet at a boundary between the double-sided circuit board and the prepreg sheet; and

the thickness of a board body of the double-sided circuit board is equal to or smaller than a distance between a surface of the prepreg sheet on a side not opposed to the double-sided circuit board and the electrode wires buried in the prepreg sheets, if the predetermined thickness of the prepreg sheet is t2′, the thickness of the board body of the double-sided circuit board is t1, and the thickness of the electrode wires is t0, there is a relation of (Formula 1) t2′=α (α is a predetermined value satisfying 1<α)·t1+k (k is a predetermined value satisfying 0<k≦1)·t0.

Further, the 11th aspect of the present invention is the multilayered circuit board according to the 10th aspect of the present invention, wherein the predetermined value a is a value corresponding to the thickness of the electrode wires.

Further, the 12th aspect of the present invention is the multilayered circuit board according to the 11th aspect of the present invention, wherein the predetermined value a is substantially 1.05.

Further, the 13th aspect of the present invention is the multilayered circuit board according to the 10th aspect of the present invention, wherein one of the electrode wires of the double-sided circuit board is a signal line and the other is a ground.

Further, the 14th aspect of the present invention is the multilayered circuit board according to the 10th aspect of the present invention, wherein the circuit board includes multiple double-sided circuit boards which includes the double-sided circuit board and multiple prepreg sheets which includes the prepreg sheet and the thickness of the prepreg sheets before the prepreg sheet is laminated on the double-sided circuit board is thicker than the thickness of the prepreg sheets forming multiple double-sided circuit boards with the thickness of the electrode wires of the double-sided circuit boards added thereto.

Further, the 15th aspect of the present invention is the multilayered circuit board according to the 10th aspect of the present invention, wherein the circuit board includes multiple double-sided circuit boards, which includes the double-sided circuit board, and multiple prepreg sheets, which include the prepreg sheet, and

a resin impregnation amount of prepreg sheets is larger than the resin impregnation amount of the prepreg sheets forming the multiple double-sided circuit boards.

Further, the 16th aspect of the present invention is the multilayered circuit board according to the 15th aspect of the present invention, wherein the resin impregnation amount of the prepreg sheets forming the double-sided circuit boards is 45 to 70 wt %.

Further, the 17th aspect of the present invention is the multilayered circuit board according to the 16th aspect of the present invention, wherein the resin impregnation amount of the prepreg sheets is 55 to 80 wt %.

Further, the 18th aspect of the present invention is the multilayered circuit board according to the 11th aspect of the present invention, wherein the circuit board includes multiple double-sided circuit boards, which includes the double-sided circuit board, and multiple prepreg sheets, which include the prepreg sheet, and a permittivity of the prepreg sheet before the prepreg sheets are laminated on the double-sided circuit board, is higher than the permittivity of the prepreg sheets forming the double-sided circuit boards.

Further, the 19th aspect of the present invention is the multilayered circuit board according to the 10th aspect of the present invention, wherein the permittivity of the prepreg sheets is lower than the permittivity of the prepreg sheets forming the double-sided circuit boards.

Further, the 20th aspect of the present invention is the multilayered circuit board according to the 10th aspect of the present invention, wherein the prepreg sheets and the prepreg sheets forming the double-sided circuit board are a composite material in which a woven fabric or a nonwoven fabric having at least one of heat-resisting organic fiber or inorganic fiber as its main component is impregnated with the thermosetting resin to be in a semi-hardened state.

Further, the 21st aspect of the present invention is the multilayered circuit board according to the 20th aspect of the present invention, wherein the thermosetting resin includes at least one or more kinds out of an epoxy resin, a phenol resin, a polyimide resin, a polyester resin, a silicon resin, a cyanate ester resin, a polyphenylene ether resin, a polyphenylene oxide resin, a fluororesin and a melamine resin.

Further, the 22nd aspect of the present invention is the method of manufacturing a multilayered circuit board according to the 5th aspect of the present invention, wherein:

alternately positioning and stacking the multiple double-sided circuit boards and other multiple prepreg sheets for manufacturing the laminated body includes placing copper foils at the beginning and end and placing the other multiple prepreg sheets adjacently to the copper foils.

Further, the 23rd aspect of the present invention is the method of manufacturing a multilayered circuit board according to the 1st aspect of the present invention, wherein:

the laminated body is manufactured by alternately positioning and stacking multiple circuit boards including a circuit pattern of two or more layers, and multiple prepreg sheets, which includes the prepreg sheet; and

said layered structure is manufactured by heating and pressurizing both top and bottom surfaces of the laminated body and hardening the multiple prepreg sheets.

Further, the 24th aspect of the present invention is the method of manufacturing a multilayered circuit board according to the 1st aspect of the present invention, wherein:

the laminated body is manufactured by alternately positioning and stacking multiple circuit boards including a circuit pattern of two or more layers, and multiple prepreg sheets, which includes the prepreg sheet; and

said layered structure is manufactured by partially heating and pressurizing an arbitrary area of the laminated body and melting and then hardening a resin included in the multiple prepreg sheets so as to bond a circuit board group.

Further, the 25th aspect of the present invention is the method of manufacturing a multilayered circuit board according to the 1st aspect of the present invention, wherein:

a plurality of the laminated bodies are manufactured by stacking either multiple circuit boards including a circuit pattern of two or more layers, or

multiple prepreg sheets, which include the prepreg sheet, one by one; and

said layered structure is manufactured by stacking the plurality of the laminated bodies, partially heating and pressurizing arbitrary areas thereof and melting and then hardening a resin included in the multiple prepreg sheets so as to mutually bond them.

Further, the 26th aspect of the present invention is the method of manufacturing a multilayered circuit board according to the 1st aspect of the present invention, wherein:

the laminated body is manufactured by stacking two circuit boards including a circuit pattern of two or more layers with one prepreg sheet sandwiched between the two circuit boards; and

said layered structure is manufactured by heating and pressurizing both top and bottom surfaces of the laminated body and hardening the multiple prepreg sheets.

Further, the 27th aspect of the present invention is the method of manufacturing a multilayered circuit board according to the 1st aspect of the present invention, wherein:

the laminated body is manufactured by stacking two circuit boards including a circuit pattern of two or more layers with one prepreg sheet sandwiched between the two circuit boards; and

said layered structure is manufactured by partially heating and pressurizing an arbitrary area of the laminated body and melting and then hardening a resin included in the multiple prepreg sheets so as to bond a circuit board group.

According to the present invention, it is possible to provide the method of manufacturing a high-performance multilayered circuit board and the multilayered circuit board, which can be stably driven at high frequencies with no mismatch in impedance.

### BRIEF DESCRIPTION OF THE DRAWINGS

FIG. 1(a) is a diagram of a double-sided circuit board showing its manufacturing method according to a first embodiment of the present invention, and FIG. 1(b) is a diagram of the double-sided circuit board showing the manufacturing method according to the first embodiment of the present invention;

FIG. 2(a) is a sectional view of a multilayered circuit board showing its manufacturing process according to the first embodiment of the present invention, FIG. 2(b) is a sectional view of the multilayered circuit board showing its manufacturing process according to the first embodiment of the present invention, and FIG. 2(c) is a sectional view showing a state of completion of the multilayered circuit board according to the first embodiment of the present invention;

FIG. 3 is a sectional view schematically showing a high frequency characteristic evaluation portion of an internal-layer portion (stripline structure) of the multilayered circuit board according to the first embodiment of the present invention;

FIG. 4(a) is a sectional view schematically showing the high frequency characteristic evaluation portion of the internal-layer portion (stripline structure) of the multilayered circuit board according to the first embodiment of the present invention, FIG. 4(b) is a sectional view schematically showing the high frequency characteristic evaluation portion of the internal-layer portion (stripline structure) of the multilayered circuit board according to the first embodiment of the present invention, and FIG. 4(c) is a sectional view schematically showing the high frequency characteristic evaluation portion of the internal-layer portion (stripline structure) of the multilayered circuit board according to the first embodiment of the present invention;

FIG. 5 is a sectional view of a portion in which two signal wirings are sandwiched by grounding links of the multilayered circuit board according to the first embodiment of the present invention;

FIG. 6 is a sectional view of the multilayered circuit board using a multilayer structure in manufacturing according to the first embodiment of the present invention;

FIG. 7 is a sectional view of the multilayered circuit board in manufacturing in the case of sandwiching it with two multilayered circuit boards according to the first embodiment of the present invention;

FIG. 8(a) is a sectional view of the multilayered circuit board showing the manufacturing process with a conventional technology, FIG. 8(b) is a sectional view of the multilayered circuit board showing the manufacturing process with the conventional technology, and FIG. 8(c) is a sectional view showing the state of completion of the multilayered circuit board with the conventional technology; and

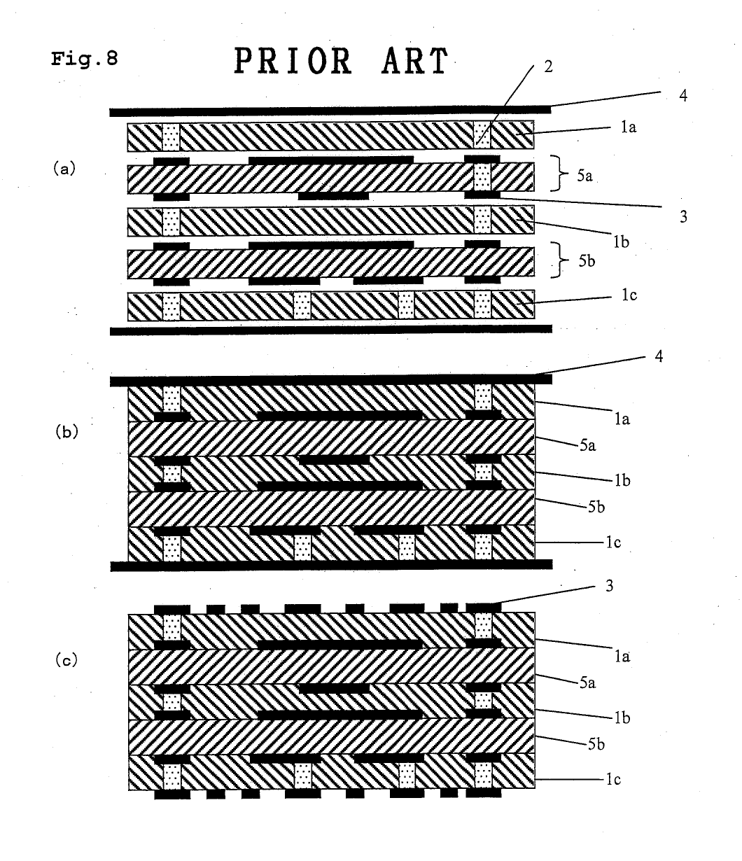

FIG. 9(a) is a sectional view schematically showing a configuration of an internal-layer portion of the multilayered circuit board using the conventional technology, FIG. 9(b) is a sectional view schematically showing the configuration of the internal-layer portion of the multilayered circuit board using the conventional technology, and FIG. 9(c) is a sectional view schematically showing the configuration of the internal-layer portion of the multilayered circuit board using the conventional technology.

### DESCRIPTION OF SYMBOLS

1a, 1b, 1c Aramid-epoxy sheets (prepregs)
2 Conductive paste
3 Circuit pattern
4a, 4b Metallic foils (copper foils)
5a, 5b Double-sided circuit boards
10, 10a, 10b, 10c, 10d, 10e Prepregs
20 Conductive paste
30 Circuit pattern
40a, 40b Metallic foils
50, 50a, 50b, 50c, 60a, 60b Double-sided circuit boards
61 4-layered circuit board
62 8-layered circuit board
70a, 70b Multilayered circuit boards
G1, G2 Grounding links
S1, S2, S3 Signal wirings

### BEST MODE FOR CARRYING OUT THE INVENTION

Hereunder, embodiments of the present invention will be described by using the drawings.

### First Embodiment

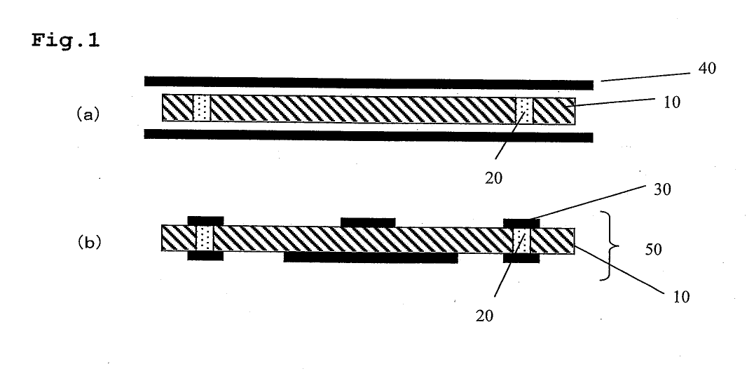

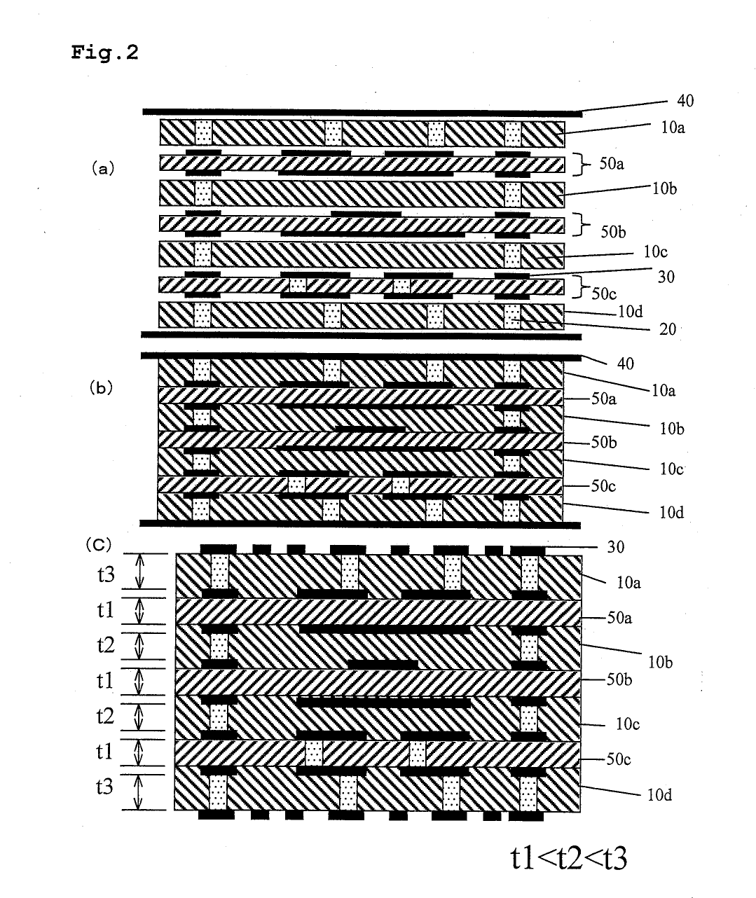

A description will be given by using FIGS. 1 and 2 as to a manufacturing procedure of a multilayered circuit board according to a first embodiment of the present invention.

First, a description will be given by using FIG. 1 as to a method of manufacturing a double-sided circuit board to be used when manufacturing an 8-layered circuit board.

FIG. 1(a) is a lamination layer sectional view of the double-sided circuit board. In FIG. 1(a), reference numeral 10 denotes a glass-epoxy sheet composed of a composite material having 80-μm thick glass fabrics impregnated with a filler-added epoxy resin (hereinafter, referred to as a prepreg). The prepreg 10 uses a resin amount of 54 wt %. The prepreg 10 has a through-holes processed and formed by a laser or the like and filled with a conductive paste 20 composed of Cu powder and the thermosetting epoxy resin.

And 12-μm thick copper foils 40 are placed on both sides of the prepreg 10 respectively so that heat and pressure (200° C., 50 kg/cm²) are applied thereto by heat press from both sides. After the heat press, circuit patterns 30 are formed from the copper foils 40 on both sides by etching so as to complete a double-sided circuit board 50.

FIG. 1(b) is a sectional view of the manufactured double-sided circuit board 50.

The circuit patterns 30 formed on both sides of the double-sided circuit board 50 are electrically connected by a conductive paste 20 filled in a through-hole provided in a predetermined position of the prepreg 10.

Next, a description will be given by using FIG. 2 as to a multilayer procedure of the 8-layered board according to this embodiment.

FIG. 2(a) is a lamination layer sectional view of the 8-layered board. In FIG. 1(a), reference characters 10a, 10b, 10c, 10d are all prepregs composed of a composite material having 100-μm thick glass fabrics impregnated with a filler-added epoxy resin. The prepregs 10a, 10b, 10c and 10d use a resin amount of 60 wt %. The prepregs 10a, 10b, 10c and 10d have the through-holes processed and formed by a laser or the like, and the through-holes are filled with the conductive paste 20 composed of Cu powder and the thermosetting epoxy resin.

The circuit patterns 30 of the double-sided circuit boards 50a, 50b and 50c cut into both or one of principal surfaces of the prepregs 10a, 10b, 10c and 10d on the heat press. As for thicknesses of the prepregs 10a, 10b, 10c and 10d after the heat press, they become thinner than before the heat press respectively. And yet they become even thinner due to influence of the circuit patterns 30 cutting into them. The circuit patterns 30 of the double-sided circuit boards 50a, 50b and 50c opposed to the prepregs 10a, 10b, 10c and 10d are different in wiring width respectively so that the influence of the circuit patterns 30 cutting into them is different and change in thickness is also different as to the prepregs 10a, 10b, 10c and 10d respectively.

To render the prepregs 10a, 10b, 10c and 10d thicker than the prepregs forming the double-sided circuit boards 50a, 50b and 50c after the heat press, the ratio of the resin amount of the prepregs for lamination 10a, 10b, 10c and 10d was rendered larger than that of the prepregs of the double-sided circuit boards 50a, 50b and 50c.

First, as shown in FIG. 2(a), a 12-μm thick metallic foil 40b, the prepreg 10d, double-sided circuit board 50c, prepreg 10c, double-sided circuit board 50b, prepreg 10b, double-sided circuit board 50a, prepreg 10a and a metallic foil 40a are sequentially laminated on a work stage (not shown). As for positioning of each of them, a positioning pattern (not shown) is used to position and stack them by image recognition or the like.

Next, heat and pressure are applied from above the metallic foil 4a on a top surface with a heated heater chip or the like (not shown) to melt resin components of the prepregs 10a, 10b, 10c and 10d, which adhere to the double-sided circuit boards 50a, 50b and 50c and the metallic foils 40a and 40b due to hardening of the resin components thereafter.

The above-mentioned multilayer lamination procedure may also be the following method.

First, as shown in FIG. 2(a), the metallic foil 40b is fixed on the work stage (not shown), and the prepreg 10d is positioned and mounted thereon. And heat and pressure are applied to a peripheral portion with a heater chip or the like (not shown) to melt the resin components of the prepreg 10d, which are hardened and fixed on the metallic foil 40b thereafter. Next, the double-sided circuit board 50c is positioned and mounted, and heat and pressure are applied to the peripheral portion with the heater chip or the like (not shown) to melt the resin components of the prepreg 10d, which are hardened and fixed on the prepreg 10d thereafter. This procedure is repeated likewise as often as desired. Lastly, the metallic foil 40a is mounted, and heat and pressure are applied to the peripheral portion with the heater chip or the like (not shown) to melt the resin components of the prepreg 10a, which are hardened to fix the metallic foil 40a and the prepreg 10a thereafter.

Next, heat and pressure (200° C., 50 kg/cm²) are applied to both top and under surfaces of the multilayer-laminated circuit board group. Thus, the prepregs 10a, 10b, 10c and 10d bond the double-sided circuit boards 50a, 50b and 50c and the metallic foils 40a and 40b. At the same time, inner via connections are made between the respective circuit patterns 30 of the double-sided circuit boards 50a, 50b and 50c and the metallic foils 40a and 40b by the conductive paste 2 filled in the through-holes of the prepregs 10a, 10b, 10c and 10d sandwiched among them respectively.

FIG. 2(b) shows a sectional view of the circuit board group after a heat press process.

It is possible to collectively obtain the 8-layered circuit board by selectively etching the metallic foils 40a and 40b of an outermost layer of the circuit board group shown in FIG. 2(b) and forming the circuit patterns 30.

FIG. 2(c) shows a sectional view of the manufactured 8-layered circuit board after the etching.

To observe a cross-section of the manufactured 8-layered circuit board of FIG. 2(c), thicknesses to of insulating layers of the double-sided circuit boards 50a, 50b and 50c used as cores in multilayer lamination are all equal. This is because, as described in FIG. 1, the double-sided circuit boards 50a, 50b and 50c used as cores were manufactured by sandwiching both the surfaces of the prepregs 10 with the metallic foils 40 and applying heat and pressure on both the top and under surfaces thereof.

As for the prepregs 10b and 10c, the circuit patterns 30 formed on the double-sided circuit boards 50a, 50b and 50c used as cores are cutting into both the principal surfaces of the prepregs 10b and 10c to be laid inside the prepregs 10b and 10c respectively. Therefore, thicknesses t2 of the prepregs 10b and 10c are finished thin after the heat press.

The prepregs 10a and 10d have the metallic foils 40a and 40b formed on one sides thereof and the double-sided circuit boards 50a and 50c placed on the other sides thereof. Therefore, the circuit patterns 30 are cutting into only one sides of the prepregs 10a and 10d to be laid inside the prepregs 10a and 10d. Thus, if the thicknesses of the prepregs 10a and 10d after the heat press are t3, the relation among the thicknesses of insulating layers is t1<t2<t3.

Here, t1 is the thinnest because the thickness of the glass fabrics of the prepregs 10 used when manufacturing the double-sided circuit boards 50a, 50b and 50c is thinner than the thickness of the glass fabrics of the prepregs 10a, 10b, 10c and 10d used in multilayer lamination.

Next, a board was actually manufactured to verify the relation of the thickness between t1 and t2.

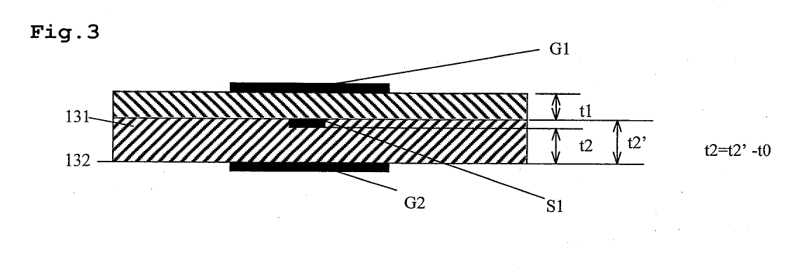

FIG. 3 is a partial cross section schematically showing a part of an internal-layer portion of the multilayered circuit board described above. This configuration takes out and schematically shows a part in a laminated state of the double-sided circuit board 50a and the prepreg 10a shown in FIG. 2(c) for instance.

In FIG. 3, the double-sided circuit board includes a grounding link G1 and a signal wiring S1 on both the principal surfaces of a prepreg 131. A prepreg 132 has a configuration in which a grounding link G2 is provided on one principal surface and the signal wiring S1 is cutting into the side joined with the double-sided circuit board to have the signal wiring S1 laid inside the prepreg 132. The signal wiring (stripline) S1 is formed between the opposed grounding link G1 and grounding link G2 so that its impedance becomes 50Ω. Length of the signal wiring S1 is 30 mm.

In FIG. 3, reference character to denotes the thickness of the prepreg 131 of the double-sided circuit board used as a core, and t2′ denotes the thickness of the prepreg 132 after the multilayer lamination. Reference character t2 denotes a result of subtracting a thickness t0 of an electrode wire for the signal wiring S1 laid inside the prepreg 132 from a thickness t2′ of the prepreg 132 after the multilayer lamination, which is an amount changeable according to the line width of the signal wiring S1, that is, a degree of cutting into the prepreg 132. The thickness of the glass fabrics of the prepreg used when manufacturing the double-sided circuit boards is thinner than the thickness of the glass fabrics of the prepreg used in multilayer lamination.

In the above configuration, the double-sided circuit boards 50a, 50b and 50c are equivalent to the double-sided circuit boards of the present invention. The prepregs 10a, 10b, 10c, 10d and 132 are equivalent to prepreg sheets of the present invention. The prepreg 131 is equivalent to a board body of the present invention. The circuit patterns 30, grounding links G1, G2 and signal wiring S1 are equivalent to the electrode wires of the present invention.

The circuit board group made by multilayer-laminating the double-sided circuit boards 50a, 50b and 50c and the prepregs 10a, 10b, 10c, and 10d stacked in a state before the heat press is equivalent to a laminated body of the present invention. A laminated structure of the double-sided circuit boards 50a, 50b and 50c and the prepregs 10a, 10b, 10c, and 10d of a completed multilayered circuit board shown in FIG. 2(c) or a laminated structure of the double-sided circuit board and the prepregs shown in FIG. 3 is equivalent to a layered structure of the present invention. According to this embodiment, the double-sided circuit board has a configuration in which the grounding link G1 and signal wiring S1 are provided as the electrode wires on the principal surfaces thereof respectively. However, the double-sided circuit board of the present invention is not restricted by applications of wiring patterns formed by the electrode wires. To be more specific, both surfaces may have the grounding links or the signal wirings.

30 multilayered circuit boards of the same specifications including the internal-layer portion shown in FIG. 3 were manufactured. Characteristic impedance and the thicknesses t1 and t2 were measured as to each of the boards.

As a result of measuring the thicknesses t1 and t2 as to each of the manufactured boards, a maximum variation of t2 was 20 μm while a maximum variation of t1 was 5 μm. To be more specific, variations in the thickness of the prepreg 131 used on the double-sided circuit board are smaller than variations in the thickness of the prepreg 132 used in multilayer lamination. This is conceivably because, as the double-sided circuit board is completed before manufacturing the entire multilayered circuit board, the prepreg 131 is not influenced by cutting-in of the signal wiring S1 when manufacturing the multilayered circuit board. As the maximum variation value 5 μm of t1 is very small, it can be said that distances of the signal wiring S1 and the grounding link G1 have become constant.

Next, the characteristic impedance was measured as to each of the boards, which was in the range of 50 to 52Ω and very good with small variations.

As described in conventional examples, if there arise variations in thickness of the prepregs which are the insulating layers, that is, to be more precise, the distance between the wirings of the double-sided circuit board and the prepregs of the layer immediately under it, the characteristic impedance value significantly changes. This appeared as a mismatch which influenced operations of mounted electronic components, such as semiconductor devices.

It is for the following reason that variations in the characteristic impedance could be put within a small range as to the multilayered circuit board of this embodiment.

The characteristic impedance of the internal-layer portion of the multilayered circuit board depends on the distances between the circuit patterns 30. In the configuration shown in FIG. 3 in particular, the relation of t1<t2 is kept between the thickness t1 of the prepreg 131 of the double-sided circuit board and the thickness t2 of (a part of) the prepreg 132 via the signal wiring 51 as in the case of FIG. 2(c). This means that the smaller thickness of the double-sided circuit board side which is smaller significantly contributes to the characteristic impedance. This suppresses the variations in the characteristic impedance.

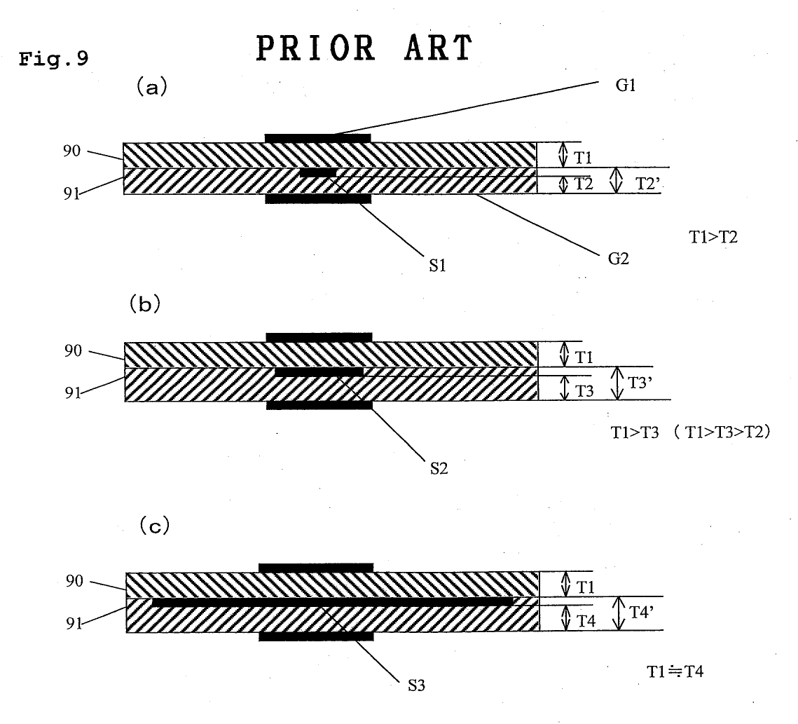

It will be further described below. As shown in FIGS. 9(a) to 9(c), in the conventional examples, the thickness of a prepreg 91 side joined with the double-sided circuit board is constantly smaller than the thickness of a prepreg 90 of the double-sided circuit board. To be more specific, this means that the thickness of the prepreg 90 side which is smaller significantly contributes as to the characteristic impedance of the conventional examples.

The prepreg 90 has significant variations in its thickness t2 because it is influenced by multiple circuit patterns of various line widths cutting into it when manufacturing the entire multilayered circuit board. The variations were a cause of the mismatch in characteristic impedance.

The present invention focuses attention on this point so that the thickness t1 of the prepreg 131 of the double-sided circuit board becomes smaller than the thickness t2 of (a part of) the prepreg 132 via the signal wiring S1 as described above. As for the characteristic impedance in this case, the thickness of the double-sided circuit board side which is smaller more significantly contributes thereto. And the prepreg 131 of the double-sided circuit board is hardened before manufacturing the entire multilayered circuit board, and so the signal wiring S1 does not cut into it, resulting in no variations in the thickness t1. Therefore, it is possible to suppress the variations in characteristic impedance under the influence of the double-sided circuit board which has a stable thickness.

Next, to further verify the result of the above actual measurement, consideration was given to a model having changed the above-mentioned condition of the thickness t2 so as to perform a simulation with a circuit simulator ADS (Agilent Technologies). In this simulation, a degree of variations was acquired by taking two kinds of the characteristic impedance reference value of 50Ω and 75Ω and permittivity ε of the prepregs in two cases of 4.6 and 3.7 acquiring calculated values (Ω) when changing the thickness t2 in both instances. The thickness t1 of the prepreg 131 is constantly fixed at 100 μm.

The thickness t1 of the double-sided circuit board side is constantly fixed at 100 μm, and three kinds of the thickness t0 of an signal wiring S1, that is, 12 μm, 18 μm and 35 μm are used.

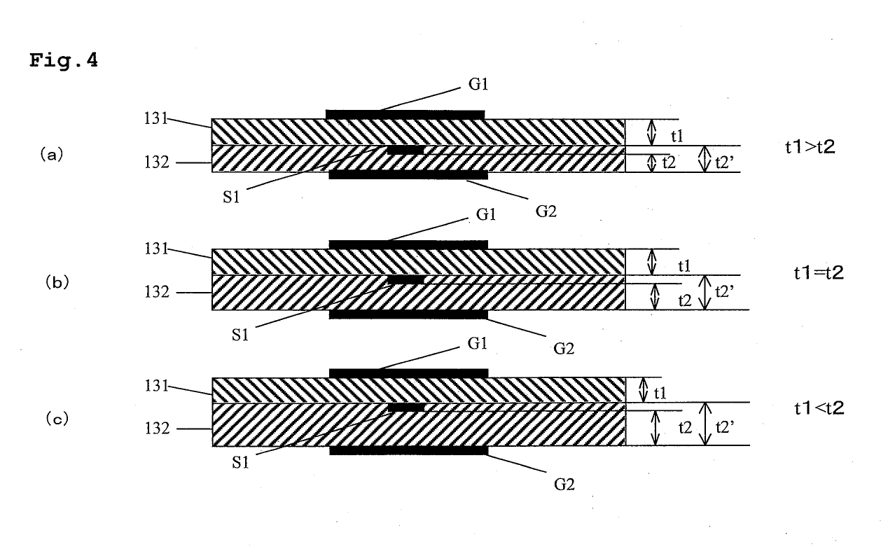

Under these conditions, the degree of variations is acquired under the conditions of t1>t2, t1=t2, and t1<t2 as with the models schematically shown in FIGS. 4(a), 4(b) and 4(c). The results are shown in (Table 1) and (Table 2).

TABLE 1

| | | Characteristic impedance | | | Characteristic impedance | | |
|---|---|---|---|---|---|---|---|
| t0 = 12 μm | | reference value = 50 Ω | | | reference value = 75 Ω | | |
| | | Line width W = | | | Line width W = | | |
| t1 | t2 | 70.03 μm | | | 11.54 μm | | |
| (μm) | (μm) | Z (Ω) | Difference Ω | Difference % | Z (Ω) | Difference Ω | Difference % |
| 100 | 80 | 47.29 | −2.71 | −5.42 | 73.07 | −1.93 | −2.57 |
| 100 | 85 | 48.02 | −1.98 | −3.96 | 73.60 | −1.40 | −1.87 |
| 100 | 90 | 48.71 | −1.29 | −2.58 | 74.09 | −0.91 | −1.21 |
| 100 | 95 | 49.37 | −0.63 | −1.26 | 74.56 | −0.44 | −0.59 |
| 100 | 100 | 50 | 0 | 0 | 75 | 0 | 0 |
| 100 | 105 | 50.56 | 0.56 | 1.12 | 75.37 | 0.37 | 0.49 |
| 100 | 110 | 51.11 | 1.11 | 2.22 | 75.72 | 0.72 | 0.96 |
| 100 | 115 | 51.63 | 1.63 | 3.26 | 76.05 | 1.05 | 1.40 |
| 100 | 120 | 52.13 | 2.13 | 4.26 | 76.37 | 1.37 | 1.83 |
| t0 = 18 μm | | 50 Ω | | | 75 Ω | | |
| t1 | t2 | W = 63.57 | | | W = 5.14 | | |
| (μm) | (μm) | Z (Ω) | Difference Ω | Difference % | Z (Ω) | Difference Ω | Difference % |
| 100 | 80 | 47.29 | −2.71 | −5.42 | 73.17 | −1.83 | −2.44 |
| 100 | 85 | 48.01 | −1.99 | −3.98 | 73.67 | −1.33 | −1.77 |
| 100 | 90 | 48.70 | −1.30 | −2.60 | 74.14 | −0.86 | −1.15 |
| 100 | 95 | 49.37 | −0.63 | −1.26 | 74.58 | −0.42 | −0.56 |
| 100 | 100 | 50 | 0 | 0 | 75 | 0 | 0 |
| 100 | 105 | 50.54 | 0.54 | 1.08 | 75.33 | 0.33 | 0.44 |
| 100 | 110 | 51.06 | 1.06 | 2.12 | 75.65 | 0.65 | 0.87 |
| 100 | 115 | 51.57 | 1.57 | 3.14 | 75.96 | 0.96 | 1.28 |
| 100 | 120 | 52.06 | 2.06 | 4.12 | 76.24 | 1.24 | 1.65 |

| t0 = 35 μm | | 50 Ω | | |
|---|---|---|---|---|
| t1 | t2 | W = 47.96 | | |
| (μm) | (μm) | Z (Ω) | Difference Ω | Difference % |
| 100 | 80 | 47.32 | −2.68 | −5.36 |
| 100 | 85 | 48.04 | −1.96 | −3.92 |
| 100 | 90 | 48.72 | −1.28 | −2.56 |
| 100 | 95 | 49.38 | −0.62 | −1.24 |
| 100 | 100 | 50 | 0 | 0 |
| 100 | 105 | 50.49 | 0.49 | 0.98 |
| 100 | 110 | 50.96 | 0.96 | 1.92 |
| 100 | 115 | 51.42 | 1.42 | 2.84 |
| 100 | 120 | 51.87 | 1.87 | 3.74 |

The table 1 is the case of permittivity ε of the prepregs=4.6, and shows the variations from the reference value of a characteristic impedance Z under the conditions of t1>t2, t1=t2, and t1<t2 per thickness t0 of the internal wiring S1. As shown in (Table 1), in the case where the thickness t0 of the internal wiring S1 is 18 μm and the characteristic impedance is 75Ω for instance, the degree of variations is different between the case of t1>t2 (difference −2.44%) and the case of t1<t2 (difference 1.65%) even if the difference between t1 and t2 is 20Ω as an absolute value which is common. The variations in the characteristic impedance are suppressed to be lower in the case of t1<t2. Even in the case of the changes based on a difference of 20 μm or less, the variations in the characteristic impedance are suppressed to be lower in the case of t1<t2. This tendency is the same even in the case where the thickness t0 of the internal wiring S1 is 12 μm and the characteristic impedance is 50Ω, that is, a line width W has become larger. To be more specific, it does not depend on the line width of the internal wiring S1. This tendency is also maintained as to the three kinds of thickness of the internal wiring t0. Therefore, the effect of suppressing the variations in characteristic impedance is obtained without depending on the form of the internal wiring.

Thus, it is understandable that the difference from the reference value is smaller and the variations in the characteristic impedance are suppressed in the case of t1<t2 even if the difference in thickness is the same.

TABLE 2

| | | Characteristic impedance | | | Characteristic impedance | | |
|---|---|---|---|---|---|---|---|
| T0 = 12 μm | | reference value = 50 Ω | | | reference value = 75 Ω | | |
| | | Line width W = | | | Line width W = | | |
| t1 | t2 | 90.22 μm | | | 24.99 μm | | |
| (μm) | (μm) | Z (Ω) | Difference Ω | Difference % | Z (Ω) | Difference Ω | Difference % |
| 100 | 80 | 47.00 | −3.00 | −6.00 | 72.40 | −2.60 | −3.47 |
| 100 | 85 | 47.81 | −2.19 | −4.38 | 73.11 | −1.89 | −2.52 |
| 100 | 90 | 48.57 | −1.43 | −2.86 | 73.78 | −1.22 | −1.63 |
| 100 | 95 | 49.30 | −0.70 | −1.40 | 74.41 | −0.59 | −0.79 |
| 100 | 100 | 50 | 0.00 | 0 | 75 | 0 | 0 |
| 100 | 105 | 50.62 | 0.62 | 1.24 | 75.52 | 0.52 | 0.69 |
| 100 | 110 | 51.24 | 1.24 | 2.48 | 76.01 | 1.01 | 1.35 |
| 100 | 115 | 51.82 | 1.82 | 3.64 | 76.48 | 1.48 | 1.97 |
| 100 | 120 | 52.39 | 2.39 | 4.78 | 76.93 | 1.93 | 2.57 |
| T0 = 18 μm | | 50 Ω | | | 75 Ω | | |
| t1 | t2 | W = 83.7 | | | W = 18.58 | | |
| (μm) | (μm) | Z (Ω) | Difference Ω | Difference % | Z (Ω) | Difference Ω | Difference % |
| 100 | 80 | 47.00 | −3.00 | −6.00 | 72.47 | −2.53 | −3.37 |
| 100 | 85 | 47.80 | −2.20 | −4.40 | 73.16 | −1.84 | −2.45 |
| 100 | 90 | 48.57 | −1.43 | −2.86 | 73.81 | −1.19 | −1.59 |
| 100 | 95 | 49.30 | −0.70 | −1.40 | 74.42 | −0.58 | −0.77 |
| 100 | 100 | 50 | 0 | 0 | 75 | 0 | 0 |
| 100 | 105 | 50.61 | 0.61 | 1.22 | 75.48 | 0.48 | 0.64 |
| 100 | 110 | 51.20 | 1.20 | 2.40 | 75.94 | 0.94 | 1.25 |
| 100 | 115 | 51.77 | 1.77 | 3.54 | 76.39 | 1.39 | 1.85 |
| 100 | 120 | 52.32 | 2.32 | 4.64 | 76.81 | 1.81 | 2.41 |
| T0 = 35 μm | | 50 Ω | | | 75 Ω | | |
| t1 | t2 | W = 68 | | | W = 3.22 | | |
| (μm) | (μm) | Z (Ω) | Difference Ω | Difference % | Z (Ω) | Difference Ω | Difference % |
| 100 | 80 | 46.99 | −3.01 | −6.02 | 72.69 | −2.31 | −3.08 |
| 100 | 85 | 47.79 | −2.21 | −4.42 | 73.32 | −1.68 | −2.24 |
| 100 | 90 | 48.56 | −1.44 | −2.88 | 73.91 | −1.09 | −1.45 |
| 100 | 95 | 49.30 | −0.70 | −1.40 | 74.47 | −0.53 | −0.71 |
| 100 | 100 | 50 | 0 | 0 | 75 | 0 | 0 |
| 100 | 105 | 50.56 | 0.56 | 1.12 | 75.40 | 0.40 | 0.53 |
| 100 | 110 | 51.10 | 1.10 | 2.20 | 75.78 | 0.78 | 1.04 |
| 100 | 115 | 51.62 | 1.62 | 3.24 | 76.14 | 1.14 | 1.52 |
| 100 | 120 | 52.13 | 2.13 | 4.26 | 76.49 | 1.49 | 1.99 |

The table 2 is the case of permittivity ε of the prepregs=3.7, and shows the variations from the reference value of the characteristic impedance Z in the case of changing the thicknesses t1 and t2 of the prepregs at the same ratio as in the table 1 with the thickness t0 of the internal wiring S1 as the same condition as in the table 1.

It is understandable that the table 2 basically shows the same tendency as (Table 1), where the variations in the characteristic impedance are suppressed in the case of t1<t2.

Thus, it is possible to provide the multilayered circuit board which can be stably driven at high frequencies with the variations in the characteristic impedance suppressed by using the layered structure in which the relation of t1<t2 holds in reference to the thickness t1 of the prepreg 131 of the double-sided circuit board of which variations are small and equalized.

Next, consideration is given to more suitable conditions for suppressing the variations in the characteristic impedance by referring to FIG. 3 again.

Fundamentally, optimal conditions for stably operating the multilayered circuit board is to match the thickness t1 of the prepreg 131 of the double-sided circuit board after manufacturing the multilayered circuit board with the thickness t2 of a portion immediately under the signal wiring S1 of the prepreg 132 and render the difference in the characteristic impedance as 0.

However, it seldom happens that the thicknesses to and t2 match due to occurrence of an error in manufacturing. Therefore, it is inevitable that the thicknesses of the prepregs will be in the relation of t1<t2 or t1>t2 in the completed multilayered circuit board.

Thus, to put the error in manufacturing in the range of t1<t2 as much as possible, a condition is set in advance to render the thicknesses of the prepregs of the double-sided circuit board smaller than an ideal value. To be more specific, it is possible, by setting the thicknesses of the prepregs in the completed multilayered circuit board in the relation of t1≦t2, to have the effect of suppressing the variations in characteristic impedance even if a deviation of thickness occurs in manufacturing.

An ideal condition of the internal-layer portion of the multilayered circuit board in the case where there is no error is to be as in the following formula 2 when the thickness of the signal wiring S1 of the double-sided circuit board is to and the thickness of the prepreg 132 is t2′.

t2=t2′−t0=t1 (Formula 2)

As a condition considering the error is t2≧t1, (Formula 2) is assigned thereto to be as follows.

t2′≧t1+t0 (Formula 3)

The thicknesses of the prepreg 131 to be the board body of the double-sided circuit board and the signal wiring S1 seldom undergo a change when manufacturing the multilayered circuit board. Therefore, the thickness t2′ of the prepreg 132 should be set so as to satisfy this condition.

The line widths and area of the circuit patterns 30 are various as shown in FIG. 2(c), and so the thickness thereof cannot be uniquely set to. For instance, in the case where the line width is larger, the circuit patterns 30 cut into the prepreg less so that the thickness theoretically becomes t0 or less without fail. Thus, t0 is multiplied by a coefficient k (0<k≦1) which has taken the line widths, area and the like into consideration, provided that the coefficient k may be substantially approximate to 1.

It is desirable that the thickness t2′ of the prepreg 132 secure a thickness equal to or more than the thickness to of a prepreg 131 to be the board body of the double-sided circuit board without fail. Therefore, to should be multiplied by a coefficient α (1≦α) which has taken this into consideration.

Eventually, it is possible, by finally defining the thickness t2′ of a prepreg 132 with the following formula 1, to obtain a manufacturing condition of the multilayered circuit board which satisfies the condition of the above (Formula 3) and suppresses the variations in characteristic impedance.

t2′=α·t1+k·t0 (Formula 1)

It is also desirable to set the coefficient α substantially larger than 1 with its upper limit around an error in a predictable range, that is, 1.05 or so to be more precise. If t1=100 μm as with the examples shown in the tables 1 and 2, it is t2′=1.05×100 (μm)+18 (μm)=123 so that t2′=105 (μm) can be acquired in the case of t0=18 μm in the table 1 for instance. If t2 becomes smaller than this value due to a manufacturing error, it means to come closer to the reference value so that the variations in characteristic impedance are suppressed to be smaller. If t2 becomes larger than this value, it is a fluctuation within the range of t1<t2 of which difference is smaller, and so the variations in characteristic impedance are suppressed to be smaller than those in the conventional examples.

The above configuration requires accuracy of the double-sided circuit board to be assured. Thus, in the case of equalizing the thickness t1 of the prepreg 131, the double-sided circuit boards 50a, 50b and 50c shown in FIG. 2 should be manufactured with a sheet-like material (such as a polyimide film) having an adhesive applied to top and under surfaces thereof.

It is also possible to provide a further high-performance board by changing permittivity of the double-sided circuit boards 50a, 50b and 50c shown in FIGS. 2(a) to 2(c) according to an object. The permittivity of the double-sided circuit boards 50a, 50b and 50c can be changed according to the kind of thermosetting resin material shown in FIG. 1 for impregnating the prepreg 10 with. For instance, it is possible to manufacture the double-sided circuit boards 50a, 50b and 50c having desired permittivity by using a combination of at least one or more kinds out of an epoxy resin, a phenol resin, a polyimide resin, a polyester resin, a silicon resin, a cyanate ester resin, a polyphenylene ether resin, a polyphenylene oxide resin, a fluororesin and a melamine resin as a thermosetting resin for impregnating the prepreg 10 with.

As for the multilayered circuit board emphasizing impedance matching in particular, the permittivity of the double-sided circuit boards 50a, 50b and 50c should be higher than that of the prepregs 10a, 10b, 10c and 10d.

As for the multilayered circuit board emphasizing a signal transmission rate, the permittivity of the double-sided circuit boards 50a, 50b and 50c should be lower than that of the prepregs 10a, 10b, 10c and 10d.

The prepregs 10 of a resin impregnation amount of 54 wt % was used when manufacturing the double-sided circuit boards 50a, 50b and 50c used as cores. It is also possible, however, to use the prepreg 10 of a resin impregnation amount other than that. It is desirable to use the prepregs of a resin impregnation amount of 45 to 70 wt % when manufacturing the double-sided circuit boards 50a, 50b and 50c.

If the resin impregnation amount of the prepregs used for the double-sided circuit boards 50a, 50b and 50c used as cores is lower than 45 wt %, the resin is so little that circuit embeddability deteriorates and blanching (a phenomenon in which a cavity is created in a board) occurs. If there is a blanched portion, there is a possibility that the board gets swollen and destroyed in a reflow process when mounting components. If the resin impregnation amount exceeds 70 wt %, a resin flow occurs when applying heat and pressure so that the conductive paste for connection flows and connections become unstable.

The prepregs 10a, 10b, 10c and 10d of a resin impregnation amount of 60 wt % were used in multilayer lamination. It is also possible, however, to use the prepregs of a resin impregnation amount other than that. It is desirable to use the prepregs of a resin impregnation amount of 55 to 80 wt % in multilayer lamination.

If the resin impregnation amount of the prepregs used in multilayer lamination is lower than 55 wt %, the resin is so little that circuit embeddability deteriorates and blanching (a phenomenon in which a cavity is created in a board) occurs. If the resin impregnation amount exceeds 80 wt %, a resin flow occurs when applying heat and pressure.

The first embodiment used the composite material having glass fabrics impregnated with a filler-added epoxy resin as the prepregs. It is also possible, however, to use a composite material wherein a woven fabric or a nonwoven fabric of which main component is one of heat-resisting organic fiber or inorganic fiber is impregnated with the thermosetting resin to be in a semi-hardened state. It is desirable that the prepregs are porous.

Surface roughness of the copper foils should be small and thickness thereof should be thin as to the copper foils used for internal-layers of the multilayered circuit board for driving a high-frequency circuit, that is, the copper foils 40 used when manufacturing the double-sided circuit board 50 shown in FIG. 1.

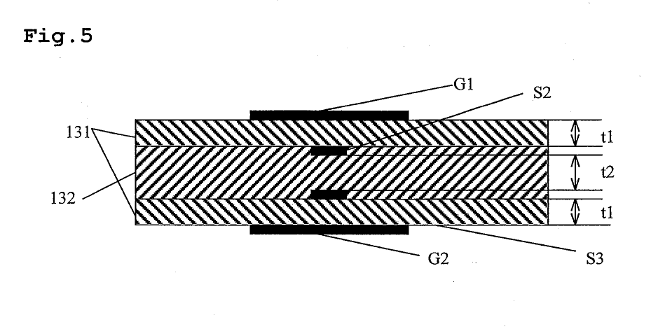

FIG. 5 shows a sectional view of the internal-layer portion of the multilayered circuit board in which the prepreg are sandwiched between two double-sided circuit boards and two signal wirings are sandwiched between grounding links. Thus, in the case where there are two signal wirings S1 and S2 between the grounding links G1 and G2, it is possible to provide the multilayered circuit board which can be stably driven at high frequencies by manufacturing the multilayered circuit board to be in the relation of t1<t2. In this case, the signal wirings S1 and S2 can be either parallel or orthogonal in the principal surface of the internal-layer portion.

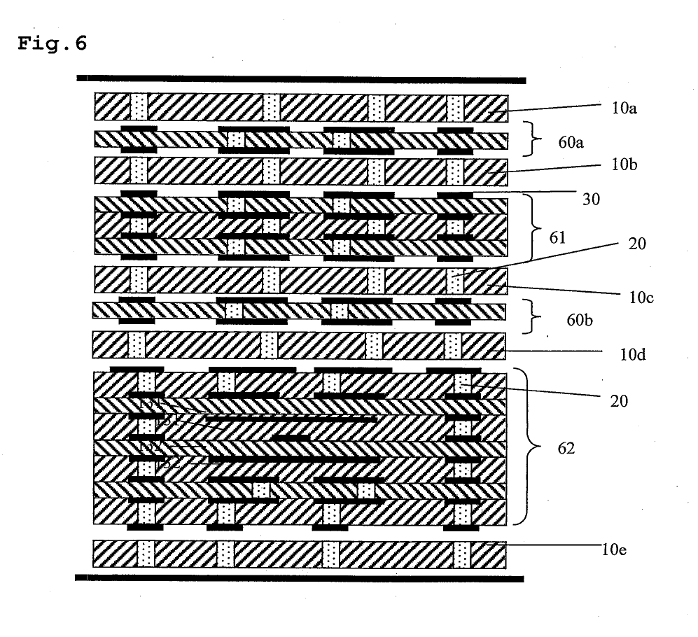

In the manufacturing of the multilayered circuit board of the first embodiment, one double-sided circuit board was used as the core. It is also possible, however, to use another multilayer board as the core. FIG. 6 shows a laminated sectional view of the multilayered circuit board in the case of using double-sided circuit boards 60a and 60b, a 4-layered circuit board 61 and an 8-layered circuit board 62. The multilayered circuit board used in this case should have a layered structure of the multilayered circuit board of the present invention, that is, a configuration made by laminating the double-sided circuit boards and prepregs as shown in FIGS. 3 and 5. It is also possible to provide a further high-performance and multifunctional circuit board by changing the permittivity of the materials used for each of the multilayered circuit boards.

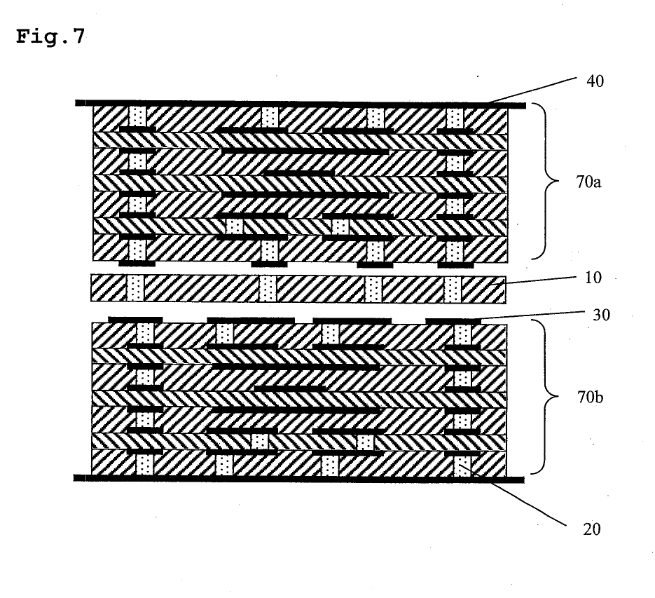

It is also possible to make further multilayered composition by using two multilayered circuit boards. FIG. 7 shows a laminated sectional view in the case of rendering two completed multilayered circuit boards 70a and 70b further multilayer with the prepreg 10. The multilayered circuit board in this case should use the multilayered circuit board with the structure of the present invention. In FIG. 7, the circuit patterns 30 are only formed on one surface of the multilayered circuit boards 70a and 70b. It is also possible, however, to use the multilayered circuit boards having the circuit patterns formed on both surfaces thereof.

The circuit board used in the first embodiment is a paste joined circuit board. It is also possible, however, to use a multilayered circuit board with a through-hole structure, a build-up structure or the like.

As is evident from the above description, it is possible to provide a high-performance multilayered circuit board for driving high-speed and high-frequency signals by equalizing the thickness of the insulating layer between the grounding link and the signal wiring. In the case of the signal wiring sandwiched between the grounding links, it is possible to easily provide a high-performance board by evening out the thickness of the thinner side of the insulating layer between the grounding link and the signal wiring. To be more specific, it is not necessary to consider control over the side where the thickness of the insulating layer between the grounding link and the signal wiring is thicker. Therefore, it becomes easier to design and manufacture the board so that multilayered boards for high-speed and high-frequency driving can be stably provided.

### INDUSTRIAL APPLICABILITY

As for the method of manufacturing a multilayered circuit board and the multilayered circuit board according to the present invention, it is possible to provide a high-performance multilayered circuit board which can be stably driven at high frequencies with no mismatch in characteristic impedance and a manufacturing method thereof. Thus, they are useful as the method of manufacturing a multilayered circuit board and the multilayered circuit board.

1. A method of manufacturing a multilayered circuit board, comprising:
manufacturing a laminated body by laminating a prepreg sheet of a predetermined thickness on at least one side of a double-sided circuit board having electrode wires patterned on both sides thereof; and
heating and pressurizing the laminated body for completing a layered structure in which the electrode wires are buried in the prepreg sheet at a boundary between the double-sided circuit board and the prepreg sheet so as to manufacture the multilayered circuit board, including said at least one layered structure, as an internal layer,
wherein, the thickness of a board body of the double-sided circuit board is equal to or smaller than a distance between a surface of the prepreg sheets on a side not opposed to the double-sided circuit board and the electrode wires buried inside the prepreg sheet in said layered structure which is completed, if the predetermined thickness of the prepreg sheets is t2′, the thickness of the board body of the double-sided circuit board is t1, and the thickness of the electrode wires is t0, there is a relation of:
t2′=α(α is a predetermined value satisfying 1≦α)·t1+k (k is a predetermined value satisfying 0<k≦1)·t0. (Formula 1)

2. The method of manufacturing a multilayered circuit board according to claim 1, wherein the predetermined value α is a value corresponding to the thickness t0 of the electrode wires.

3. The method of manufacturing a multilayered circuit board according to claim 2, wherein the predetermined value α is substantially 1.05.

4. The method of manufacturing a multilayered circuit board according to claim 1, wherein:
the laminated body is manufactured by alternately positioning and stacking multiple double-sided circuit boards, which includes the double-sided circuit board, and multiple prepreg sheets, which includes the prepreg sheet; and
said layered structure is manufactured by heating and pressurizing both top and bottom surfaces of the laminated body and hardening the multiple prepreg sheets.

5. The method of manufacturing a multilayered circuit board according to claim 1, wherein:
the laminated body is manufactured by alternately positioning and stacking multiple double-sided circuit boards, which includes the double-sided circuit board, and multiple prepreg sheets, which includes the prepreg sheet; and
said layered structure is manufactured by partially heating and pressurizing an arbitrary area of the laminated body and melting and then hardening a resin included in the multiple prepreg sheets so as to bond a circuit board group.

6. The method of manufacturing a multilayered circuit board according to claim 1, wherein:
a plurality of the laminated bodies are manufactured by stacking either multiple double-sided circuit boards, which includes the double-sided circuit board, or multiple prepreg sheets, which include the prepreg sheet, one by one; and
said layered structure is manufactured by stacking the plurality of the laminated bodies, partially heating and pressurizing arbitrary areas thereof and melting and then hardening a resin included in the multiple prepreg sheets so as to mutually bond them.

7. The method of manufacturing a multilayered circuit board according to claim 4, wherein:
alternately positioning and stacking the multiple double-sided circuit boards and the multiple prepreg sheets for manufacturing the laminated body includes placing copper foils at the beginning and end and placing the multiple prepreg sheets adjacently to the copper foils.

8. (canceled)

9. (canceled)

10. A multilayered circuit board including, as an internal layer, at least one layered structure composed of a double-sided circuit board having electrode wires patterned on both sides thereof and a prepreg sheet laminated on at least one side of the double-sided circuit board, wherein:
the electrode wires are buried in the prepreg sheet at a boundary between the double-sided circuit board and the prepreg sheet; and
the thickness of a board body of the double-sided circuit board is equal to or smaller than a distance between a surface of the prepreg sheet on a side not opposed to the double-sided circuit board and the electrode wires buried in the prepreg sheet, if the predetermined thickness of the prepreg sheets is t2′, the thickness of the board body of the double-sided circuit board is t1, and the thickness of the electrode wires is t0, there is a relation of (Formula 1)
t2′=α (α is a predetermined value satisfying 1<α)·t1+k (k is a predetermined value satisfying 0<k≦1)·t0.

11. The multilayered circuit board according to claim 10, wherein the predetermined value α is a value corresponding to the thickness of the electrode wires.

12. The multilayered circuit board according to claim 11, wherein the predetermined value α is substantially 1.05.

13. The multilayered circuit board according to claim 10, wherein one of the electrode wires of the double-sided circuit board is a signal line and the other is a ground.

14. The multilayered circuit board according to claim 10, wherein the circuit board includes multiple double-sided circuit boards which includes the double-sided circuit board and multiple prepreg sheets which includes the prepreg sheet and the thickness of the prepreg sheets before the prepreg sheet is laminated on the double-sided circuit board is thicker than the thickness of the prepreg sheets forming multiple double-sided circuit boards with the thickness of the electrode wires of the double-sided circuit boards added thereto.

15. The multilayered circuit board according to claim 10, wherein the circuit board includes multiple double-sided circuit boards, which includes the double-sided circuit board, and multiple prepreg sheets, which include the prepreg sheet, and
a resin impregnation amount of prepreg sheets is larger than the resin impregnation amount of the prepreg sheets forming the multiple double-sided circuit boards.

16. The multilayered circuit board according to claim 15, wherein the resin impregnation amount of the prepreg sheets forming the double-sided circuit boards is 45 to 70 wt %.

17. The multilayered circuit board according to claim 16, wherein the resin impregnation amount of the prepreg sheets is 55 to 80 wt %.

18. The multilayered circuit board according to claim 11, wherein the circuit board includes multiple double-sided circuit boards, which includes the double-sided circuit board, and multiple prepreg sheets, which include the prepreg sheet, and a permittivity of the prepreg sheet before the prepreg sheets are laminated on the double-sided circuit board, is higher than the permittivity of the prepreg sheets forming the double-sided circuit boards.

19. The multilayered circuit board according to claim 10, wherein the permittivity of the prepreg sheets is lower than the permittivity of the prepreg sheets forming the double-sided circuit boards.

20. The multilayered circuit board according to claim 10, wherein the prepreg sheets and the prepreg sheets forming the double-sided circuit board are a composite material in which a woven fabric or a nonwoven fabric having at least one of heat-resisting organic fiber or inorganic fiber as its main component is impregnated with the thermosetting resin to be in a semi-hardened state.

21. The multilayered circuit board according to claim 20, wherein the thermosetting resin includes at least one or more kinds out of an epoxy resin, a phenol resin, a polyimide resin, a polyester resin, a silicon resin, a cyanate ester resin, a polyphenylene ether resin, a polyphenylene oxide resin, a fluororesin and a melamine resin.

22. The method of manufacturing a multilayered circuit board according to claim 5, wherein:
alternately positioning and stacking the multiple double-sided circuit boards and other multiple prepreg sheets for manufacturing the laminated body includes placing copper foils at the beginning and end and placing the other multiple prepreg sheets adjacently to the copper foils.

23. The method of manufacturing a multilayered circuit board according to claim 1, wherein:
the laminated body is manufactured by alternately positioning and stacking multiple circuit boards including a circuit pattern of two or more layers, and multiple prepreg sheets, which includes the prepreg sheet; and
said layered structure is manufactured by heating and pressurizing both top and bottom surfaces of the laminated body and hardening the multiple prepreg sheets.

24. The method of manufacturing a multilayered circuit board according to claim 1, wherein:
the laminated body is manufactured by alternately positioning and stacking multiple circuit boards including a circuit pattern of two or more layers, and multiple prepreg sheets, which includes the prepreg sheet; and
said layered structure is manufactured by partially heating and pressurizing an arbitrary area of the laminated body and melting and then hardening a resin included in the multiple prepreg sheets so as to bond a circuit board group.

25. The method of manufacturing a multilayered circuit board according to claim 1, wherein:
a plurality of the laminated bodies are manufactured by stacking either multiple circuit boards including a circuit pattern of two or more layers, or multiple prepreg sheets, which include the prepreg sheet, one by one; and
said layered structure is manufactured by stacking the plurality of the laminated bodies, partially heating and pressurizing arbitrary areas thereof and melting and then hardening a resin included in the multiple prepreg sheets so as to mutually bond them.

26. The method of manufacturing a multilayered circuit board according to claim 1, wherein:
the laminated body is manufactured by stacking two circuit boards including a circuit pattern of two or more layers with one prepreg sheet sandwiched between the two circuit boards; and
said layered structure is manufactured by heating and pressurizing both top and bottom surfaces of the laminated body and hardening the multiple prepreg sheets.

27. The method of manufacturing a multilayered circuit board according to claim 1, wherein:
the laminated body is manufactured by stacking two circuit boards including a circuit pattern of two or more layers with one prepreg sheet sandwiched between the two circuit boards; and
said layered structure is manufactured by partially heating and pressurizing an arbitrary area of the laminated body and melting and then hardening a resin included in the multiple prepreg sheets so as to bond a circuit board group.
